(19) United States
(12) Patent Application Publication
(10) Pub. No.: US 2009/0297986 A1
(43) Pub. Date: Dec. 3, 2009

(54) METHOD OF MANUFACTURING SEMICONDUCTOR DEVICE

(75) Inventor: Masashige MORITOKI, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 12/474,476

(22) Filed: May 29, 2009

(30) Foreign Application Priority Data
Jun. 2, 2008 (JP) 2008-145058
Jun. 2, 2008 (JP) 2008-145061

(51) Int. Cl. G03F 7/20

(52) U.S. Cl. 430/312

(57) ABSTRACT

A method of manufacturing a semiconductor device includes: forming a negative resist film having an annular pattern that masks an outer peripheral part of a wafer, on a film to be processed which is formed on the wafer; forming a positive resist film having a predetermined pattern on the negative resist film; and etching the film to be processed using the negative resist film and the positive resist film as a mask.

This application is based on Japanese patent application Nos. 2008-145058 and 2008-145061, the contents of which are incorporated hereinto by reference.

### BACKGROUND

1. Technical Field

The present invention relates to a method of manufacturing a semiconductor device.

2. Related Art

A resist film is used as a mask used at the time of implanting impurity ions or the like or performing etching such as wet etching or dry etching so far.

Japanese Patent Application Laid-Open (JP-A) No. H02-82517 describes a pattern forming method of selectively exposing a peripheral part of a wafer to light with a negative resist. In the method, exposed area from the peripheral part of the wafer is varied.

JP-A No. 2005-311024 describes a technique of shielding a peripheral part of a resist on a wafer from a light. In the described method, a resist film on a target film to be etched is formed, then, a light shielding agent having light absorptivity to an exposure light during rotation of the wafer is injected through a fluid nozzle, and a light shield film is formed by heat treatment. After that, the resist film is exposed in a predetermined pattern and is subjected to etching. As a result, the resist pattern under the light shield film is not developed but remains in the peripheral part of the wafer. It is described that consequently, exposure of a copper interconnect line layer in damascene process can be prevented without decreasing the number of chips formed per wafer due to a dummy shot.

JP-A No. S56-55950 describes a technique of forming a pattern using two resist layers. In this method, features in the peripheral part of a wafer are formed by using a negative resist film, and then features in the central part of the wafer are formed by using a positive resist. It is described that by the technique, pin holes which tend to be distributed in the positive resist are compensated by the negative resist, and resolution is undertaken by the positive resist, so that high resolution can be realized.

JP-A No. 2002-57094 describes a technique of performing LOCOS oxidation using a side-rinsed photoresist for a silicon wafer, formation of a polysilicon film, N-type impurity diffusion using a side-rinsed photoresist, and P-type impurity diffusion using a side-rinsed photoresist. The outer peripheral end of the photoresist is set to the outer periphery side more than the outer peripheral end of the photoresist in the preceding process. It is described that in such a manner, an inconvenience caused by a plurality of processes using side-rinsed photoresists can be avoided

JP-A No. 2006-294759 describes a method of manufacturing a semiconductor device, including: forming a silicide layer on a surface region of a silicon substrate in a second region except for a first region having an almost band shape at a periphery of the silicon substrate; forming an insulating film on the entire surface of the silicon substrate; forming a resist film on the insulating film and forming openings in the resist film by exposure process to form a pattern; and selectively etching the insulating film using the resist film in which the pattern is formed as a mask. It is described that by this method, in the case of forming a recess in the first region and forming a conductive plug in the recess, the conductive plug and the silicon substrate do not come into contact with each other via the silicide layer, so that degradation of the silicon substrate can be prevented.

However, the conventional techniques have the following problems.

When the resist material is applied to the wafer, if the resist material is applied to the outer edge portion of the wafer, there is the possibility that the resist material comes into contact with a carrier of the wafer, an equipment carrier, or the like during carriage of the wafer and is peeled off, and peeling offs as dusts are created. Consequently, after the resist material is applied to the wafer, it is common to remove the resist material on the back side, the bevel, and the peripheral part by a back-rinse and side-rinse mechanism with an organic solvent mounted in a coater.

FIGS. 2A to 2C are cross sectional views showing an end part of the wafer 102. The end face of the wafer 102 is rounded to be a bevel. When the resist material 210 is formed on the surface (the top face in the diagram) of the wafer 102, as shown in FIG. 2A, the resist material 210 is also deposited on the outer peripheral part, the bevel, and the back side (the under face in the diagram) of the wafer 102. FIG. 2B shows a state where the back rinse is performed. FIG. 2C shows a state where the side rinse is performed.

When such back rinse and side rinse is performed, no resist exists in the peripheral part, so that creation of dusts as peeling offs of the resist material can be prevented. However, in a process of implanting impurity ions or the like, the impurity ions are always implanted in the peripheral part, and the concentration of impurity ions in the peripheral part becomes very high.

FIGS. 15A to 15C are diagrams showing the relation between a shot region 204 and a valid region 202 in which valid elements are formed at the time of applying a resist material (not shown) to a wafer 102 and exposing it. In the diagrams, the valid region 202 shown by a broken line is a region in which valid elements are formed.

FIG. 15A is a diagram showing the shot region 204 in which shot exposure is performed for the shot regions 204 when all area of which are included in the valid region 202 (valid shot). FIG. 15B is a diagram showing the shot region 204 in which shot exposure is performed not only for the shot regions 204 when all area of which are included in the valid region 202 but also for the shot regions 204 when a part of which are included in the valid region 202 (normal shot). FIG. 15C is a diagram showing the shot region 204 in which shot exposure is performed for all of the regions overlapping the wafer 102 (full-face shot).

In the case of performing the normal shot shown in FIG. 15B or the full-face shot shown in FIG. 15C, there is an advantage that the number of valid chips which can be obtained from a single wafer increases. On the other hand, in the case of performing shot exposure also on the outside of the valid region 202 such as normal shot or full-face shot, a region in which the resist film does not exist continuously is created in a range from the outer periphery of the wafer to the valid region 202. When such a region exists, for example, even if there is a region in which impurity ion implantation or film etching is not desired, in order to prevent a peel-off from the outer periphery of the wafer or defects, the region cannot be protected with the resist film.

In the technique of JP-A No. H02-82517, the resist film is formed in the outer peripheral part. However, there is a problem that a negative resist film has, generally, low resolution and cannot match microfabrication. As described in JP-A No. 2005-311024, the technique of forming a light shield film by using a light shielding agent, microfabrication cannot be performed with high controllability. In the technique of JP-A No. S56-55950, the negative resist film is formed in a part outside of the region to be opened in the positive resist film to compensate pin holes occurring in the positive resist film. However, the outer peripheral part of the wafer is not selectively protected.

In the technique of JP-A No. 2002-57094, both of the N-type impurity ions and the P-type impurity ions are not implanted in the outer peripheral part of the wafer. However, it is necessary to control the outer peripheral end of the photoresist film every process, and the process is complicated. The technique cannot match the normal shot and the full-face shot.

In the technique of JP-A No. 2006-294759, to provide a region for not forming a silicide layer, a shadow ring is used. However, in the case of using a shadow ring, a problem occurs such that the valid region is narrowed.

### SUMMARY

In one embodiment of the present invention, there is provided a method of manufacturing a semiconductor device, including: forming a negative resist film having an annular pattern that masks an outer peripheral part of a wafer, on a film to be processed which is formed on the wafer; forming a positive resist film having a predetermined pattern on the negative resist film; and etching the film to be processed using the negative resist film and the positive resist film as a mask.

With the configuration, while forming the annular pattern by the resist film in the outer peripheral part of the wafer and protecting the region, in the valid region in the wafer, patterning of high resolution can be performed.

In another embodiment of the present invention, there is provided a method of manufacturing a semiconductor device, including: forming a first resist film on a wafer, the first resist film being obtained by removing a first outer peripheral region having a first width from an outer edge of the wafer and, using the first resist film as a mask, implanting impurity ions of a first conductive type into the wafer; forming a second resist film on the wafer, the second resist film being obtained by removing a second outer peripheral region having a second width from the outer edge of the wafer and, using the second resist film as a mask, implanting impurity ions of a second conductive type into the wafer; forming a block insulating film on the entire surface of the wafer; forming a third resist film having a first pattern on the block insulating film and patterning the block insulating film with the third resist film; and forming a silicide layer on the wafer using the block insulating film as a mask, wherein in the patterning the block insulating film, the first pattern of the third resist film includes an annular pattern that masks an outer peripheral part of the wafer, and an inner edge of the annular pattern is positioned on an inner peripheral side of at least an inner edge of a region where the first and second outer peripheral regions overlap.

By the method, the end part of the silicide layer can be controlled so as not to be positioned on the high-concentration impurity ion implantation region in which both of impurity ions of a first conductive type and impurity ions of a second conductive type are implanted, and peeling-off of the silicide layer can be prevented.

Arbitrary combinations of the components, and expressions of the present invention changed from the methods to apparatuses or the like are also valid as aspects of the present invention.

According to the present invention, while protecting the outer peripheral part of the wafer with the resist film, patterning of high resolution can be performed.

According to the present invention, at the time of forming the silicide layer on the surface of the wafer, the end part of the silicide layer can be controlled so as not to be formed on the region in which impurity ions of high concentration are implanted.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a flowchart showing a procedure of manufacturing a semiconductor device in an embodiment of the present invention;

FIGS. 2A to 2C are cross sectional views showing an end part of a wafer;

FIGS. 3 and 4 are flowcharts each showing a procedure of manufacturing the semiconductor device in the embodiment of the invention;

FIGS. 5A to 5C are plan views showing a part of a wafer;

FIGS. 6A to 6C to FIGS. 12A to 12C are process cross sections for concretely explaining the procedure of manufacturing the semiconductor device in the embodiment of the present invention;

FIGS. 13 and 14 are plan views showing a state where a negative resist film is formed on the wafer;

FIGS. 15A to 15C are diagrams showing the relation between a shot region and a valid region in which a valid element is formed at the time of applying a resist material on the wafer and exposing it;

FIG. 16 is a diagram showing an example of using a shadow ring at the time of forming a metal layer;

FIG. 17 is a diagram showing an example using no shadow ring at the time of forming a metal layer;

FIG. 18 is a flowchart showing a procedure of manufacturing a semiconductor device in the embodiment of the present invention; and

FIGS. 19A to 19C are process cross sections for concretely explaining the procedure of manufacturing the semiconductor device in the embodiment of the invention.

### DETAILED DESCRIPTION

The invention will now be described with reference to illustrative embodiments. Those skilled in the art will recognize that various alternative embodiments can be accomplished using the teachings herein, and that the invention is not limited to exemplary embodiments illustrated for explanatory purposes.

Embodiments of the present invention will be described below with reference to the drawings. In all of the drawings, similar reference numerals are designated to similar components and repetitive description will not be given.

The inventors of the present invention have found a problem that, at the time of forming a silicide layer on the wafer (semiconductor wafer such as a silicon wafer for example) by silicidation of the surface of a wafer, when impurity ions of high concentration are implanted in the wafer, peeling off of the silicide layer tends to occur. The process of implanting impurity ions into the wafer includes a process of implanting N-type impurity ions and a process of implanting P-type impurity ions. In a valid region in the wafer, for example, in the process of implanting N-type impurity ions, a region in which N-type impurity ions need not be implanted is covered with the resist film, and the N-type impurity ions are not implanted in the region. On the other hand, in the process of implanting P-type impurity ions, a region in which P-type impurity ions need not be implanted is covered with the resist film, and the P-type impurity ions are not implanted in the region. However, when the back rinse and the side rinse as described above is performed, in the peripheral part of the wafer, in any of the processes, the impurity ions are implanted. Consequently, the peripheral part is in a state where very-high-concentration impurities are implanted. Therefore, when a silicide layer is formed in the peripheral part of the wafer, there is a problem that film peeling off occurs. In particular, in the case where normal shot or full-face shot of exposing also the peripheral part is performed, depending on the pattern, a region in which the resist film does riot exist continuously is created in a range from the outer edge of the wafer to the valid region. Therefore, the silicide layer is formed continuously from the peripheral part to the valid region, and there is a problem that film peeling off tends to occur.

Conventionally, however, a countermeasure from such a viewpoint is not taken, and there is a challenge.

In the techniques described in JP-A Nos. H02-82517, 2005-311024, S56-55950, and 2002-57094, a control considering a region or the like in which impurity ions are implanted and a region in which the silicide layer is formed is not performed. In the technique described in JP-A No. 2002-57094, in the outer peripheral part of the wafer, both of the N-type impurity ions and the P-type impurity ions are prevented from being implanted. However, it is necessary to control the outer peripheral end of the photoresist film process by process, and the process becomes complicated. At any rate, a region in which the P-type impurity ions and the N-type impurity ions are implanted is created in the outer peripheral part.

Also in the technique described in JP-A No. 2006-294759, a control considering a region or the like in which impurity ions are implanted and a region in which the silicide layer is formed is not performed. To provide a region for not forming the silicide layer, a shadow ring is used. However, in the case of using the shadow ring, there is a case that the metal layer in the outer peripheral part becomes thin, and the silicide formation phase in the part changes. Consequently, at the time of performing residual etching on the metal layer, the surface of the silicide layer is oxidized, and a silicide layer having a film quality different from that of the effective region on the inside is formed. When such an oxide film is formed on the surface of the silicide layer, in the case of forming an insulating film such as an SiN film on the silicide layer, a problem of peeling-off of the insulating film occurs.

### First Embodiment

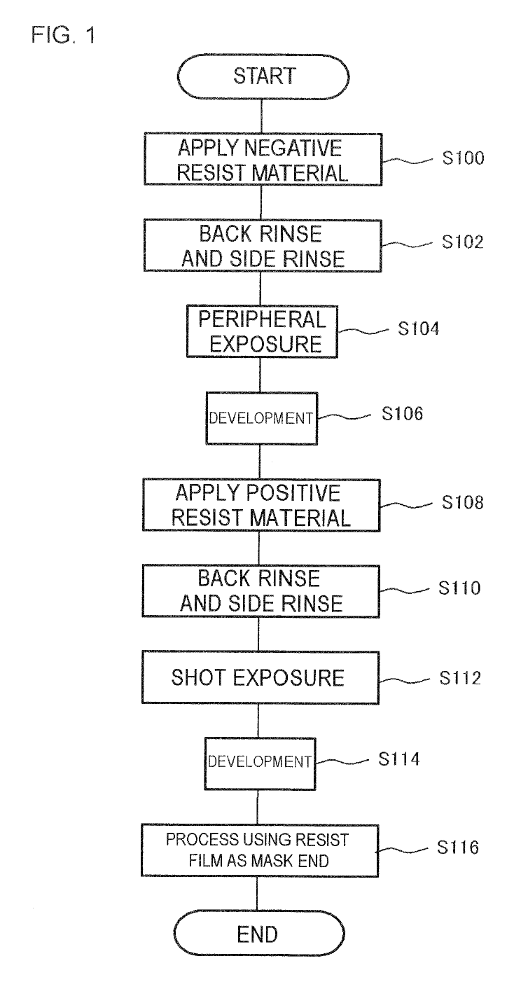

FIG. 1 is a flowchart showing a procedure of manufacturing a semi-conductor device in the embodiment.

First, a negative resist material is applied to the entire surface of a wafer (S100). Subsequently, the back and sides are rinsed (S102) After that, peripheral exposure of annularly exposing a peripheral part of the wafer is performed (S104), and development is performed (S106). While irradiating the negative resist material in an outer peripheral part of the wafer with light from an exposure source, the wafer is rotated relative to the exposure source. It is sufficient to rotate the wafer relative to the exposure source. By fixing either the wafer or the exposure source and rotating the other, the peripheral exposure can be performed. Since the negative resist material is used, the annular negative resist film is formed in the peripheral part of the wafer. Subsequently, the positive resist material is applied to the entire surface of the wafer (S108) The back and sides are rinsed (S110).

After that, using a reticule in which an opening in a desired pattern is formed, shot exposure is performed a plurality of times on the wafer (S112), and development is performed (S114). As a result, the positive resist film in which the opening in the desired pattern is formed on the wafer 102 is formed. After that, a resist film as a stacked film of the negative resist film formed in step S106 and the positive resist film formed in step S114 is used as a mask, and a process such as implantation of impurity ions or etching is performed (S116).

In the following embodiment, the case of using a stack-layered film of a negative resist film and a positive resist film at the time of patterning a silicide block insulating film that protects a part which is not desired to be subjected to silicide formation when silicide is applied to the surface of a wafer will be described as an example.

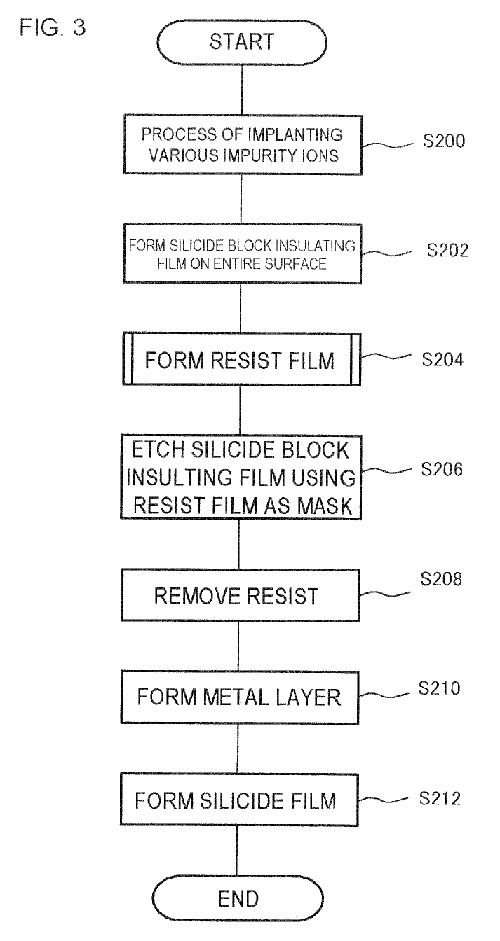

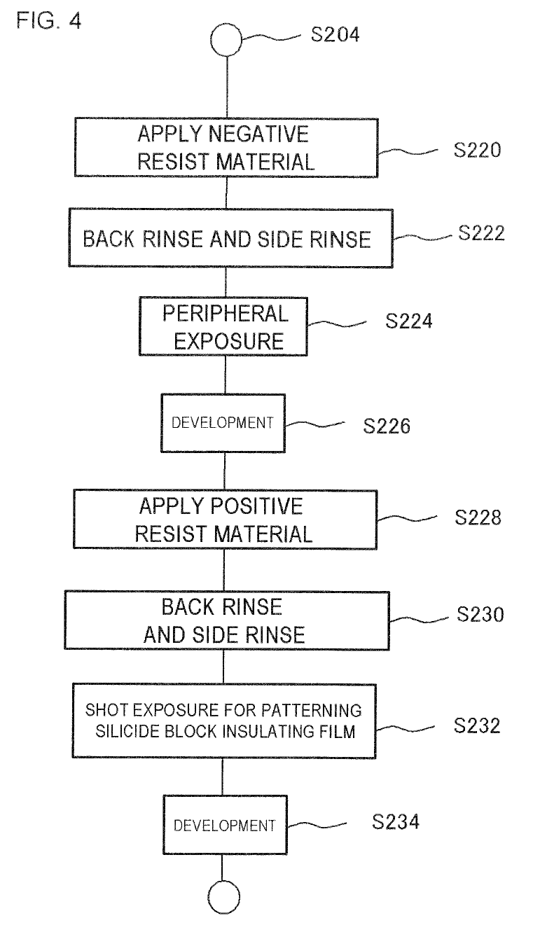

FIGS. 3 and 4 are flowcharts showing a procedure of manufacturing a semiconductor device in the embodiment.

First, a process of implanting various impurity ions for forming an impurity diffusion layer such as a source/drain region of a transistor and an extension region is performed (S200).

The impurity ion implanting process may include a process of forming a first resist film on a wafer, the first resist film being obtained by removing a first outer peripheral region having a first width from the outer edge of the wafer and, using the first resist film as a mask, a process of implanting impurity ions of a first conductive type into the wafer; and a process of forming a second resist film on the wafer, the second resist film being obtained by removing a second outer peripheral region having a second width from the outer edge of the wafer and, using the second resist fill as a mask, a process of implanting impurity ions of a second conductive type into the wafer. The first conductive type and the second conductive type are a P type and an N type, or an N type or a P type, respectively. The first width of the first outer peripheral region and the second width of the second outer peripheral region may be equal to each other or may he different from each other. Further, each of the process of implanting the impurity ions of the first conductive type into the wafer and the process of implanting the impurity ions of the second conductive type into the wafer may be a process for forming a source/drain region of a transistor.

Subsequently, on the entire surface of the wafer, a silicide block insulating film (block insulating film) is formed (S202). After that, a resist film (third resist film) having a first pattern for patterning the silicide block insulating film is formed (S204). The first pattern of the resist film includes an annular pattern that masks the outer peripheral part of the wafer and a predetermined pattern (second pattern) formed every predetermined range. The inner edge of the annular pattern is positioned on an inner peripheral side of at least an inner edge of a region where the first and second outer peripheral regions in step S200 overlap. More preferably, the inner edge of the annular pattern is positioned on the inner peripheral side of the inner edge of the first or second outer peripheral region more than the inner edge of the other region.

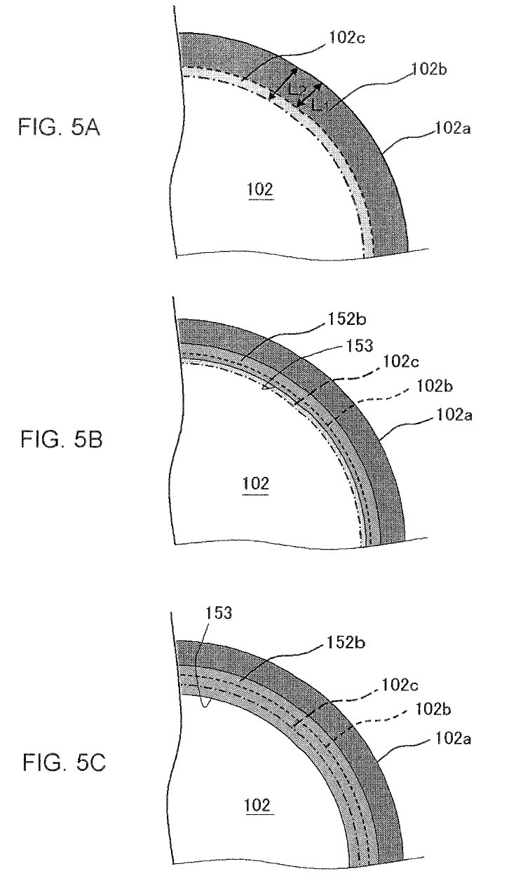

This state is shown in FIGS. 5A to 5C. FIGS. 5A to 5C are plan views each showing a part of the wafer 102.

FIG. 5A shows a first outer peripheral region 102b and a second outer peripheral region 102c described in step S200. The case where a first width L₁ from the outer edge 102a of the wafer of the first outer peripheral region 102b is narrower than a second width L₂ from the outer edge 102a of the wafer of the second outer peripheral region 102c is shown In the first outer peripheral region 102b, both of impurity ions of the first conductive type and impurity ions of the second conductive type are implanted. In a region between the inner edge of the first outer peripheral region 102b and the inner edge of the second outer peripheral region 102c, the impurity ions of the second conductive type are implanted.

FIGS. 5B and 5C are diagrams each showing an annular pattern that masks the outer peripheral part of the wafer of a negative resist film 152b formed on the wafer 102 in the state illustrated in FIG. 5A. In the example shown in FIG. 5B, an inner edge 153 of the annular pattern is positioned on the inner peripheral side of the inner edge of a region where the first and second outer peripheral regions 102b and 102c overlap, that is, the inner edge of the first outer peripheral region 102b.

In the example shown in FIG. 5C, the inner edge 153 of the annular pattern is positioned on the inner peripheral side of the inner edge of one of the first and second outer peripheral regions 102b and 102c, which is positioned on the inner peripheral side, that is, the inner edge of the second outer peripheral region 102c. Further, the annular pattern may have a configuration obtained by eliminating the outer peripheral region having a predetermined width (a third width) from the outer edge 102a of the wafer.

Although the case where the first width L₁ is narrower than the second width L₂ is shown in FIGS. 5A to 5B, alternatively, the second width L₂ may be narrower than the first width L₁. Alternatively, the first width L₁ and the second width L₂ may be almost equal to each other

Referring again to FIG. 3, after that, the resist film having the first pattern is used as a mask, and the silicide block insulting film is etched and patterned (S206). After that, the resist film is removed (S208). Subsequently, a metal layer is formed on the entire face of the wafer (S210). In the embodiment, at the time of forming the metal layer, a shadow ring may be used.

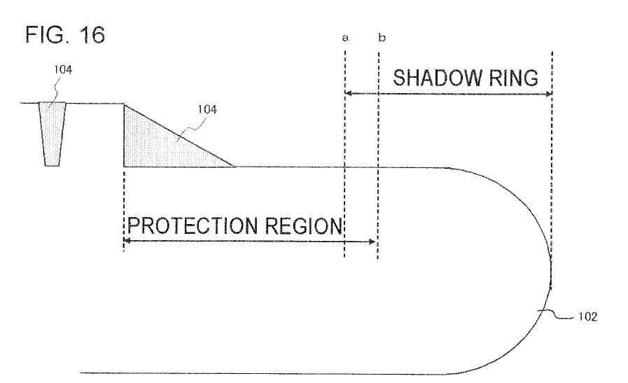

FIG. 16 is a diagram showing a region in which the metal layer is formed on the wafer 102 and a region to be protected by the silicide block insulating film in the case of using the shadow ring. A region from the end face of the wafer 102 to a broken line “a” is a region in which the metal layer is riot formed due to the influence of the shadow ring. The width of the region from the end face of the wafer 102 to the broken line “a” may be set to, for example, about 1 mm. On the other hand, a region from the inside of the wafer 102 to broken line “b” is a region to be protected by a silicide block insulating film. In the embodiment, the broken line “b” may be set to be positioned on the outer peripheral side of the broken line “a”. That is, in the embodiment, the outer edge of the annular pattern that masks the outer peripheral part of the wafer may be set to be positioned on the outer peripheral side of the broken line “b” shown in FIG. 16. With the configuration, in the case of using the shadow ring, a problem that the metal layer in the outer peripheral part becomes thin and the silicide formation phase in the part changes can be prevented. That is, by providing the silicide block insulating film under the end of the outer peripheral part in which the metal layer is formed, creation of a part in which the metal layer in the outer peripheral part is thin can be prevented.

Referring again to FIG. 3, silicide forming process is performed (S212). In the process, using the silicide block insulating film as a mask, silicide is formed on the surface of the wafer which is not covered with the silicide block insulating film. In such a manner, the end part of the silicide layer can be controlled so as not to be positioned on the region in which high-concentration impurity ions are implanted, in the outer peripheral part of the wafer.

FIG. 4 shows a procedure of forming a resist film for patterning the silicide block insulting film in the embodiment.

First, a negative resist material is applied to the entire surface of a wafer (S220). Subsequently, the back and sides are rinsed (S222). After that, peripheral exposure of annularly exposing a peripheral part of the wafer is performed (S224), and development is performed (S226). While irradiating the negative resist material in an outer peripheral part of the wafer with light from an exposure source, the wafer is rotated relative to the exposure source. It is sufficient to rotate the wafer relative to the exposure source. By fixing either the wafer or the exposure source and rotating the other, the peripheral exposure can be performed. Since the negative resist material is used, the annular negative resist film is formed in the peripheral part of the wafer. Subsequently, the positive resist material is applied to the entire surface of the wafer (S228). The back and sides are rinsed (S230).

After that, using a reticle in which an opening is formed in a portion in which a silicide layer is desired to be formed, the shot exposure for patterning the silicide block insulating film is performed a plurality of times (S232) and development is performed (S234). As a result, the negative resist film is formed in the peripheral part of the wafer, and the positive resist film having the opening in the portion where the silicide layer is desired to be formed is formed in the valid region 202. In step S206 in FIG. 3, using a stacked resist film of the negative and positive resist films as a mask, the silicide block insulating film is etched.

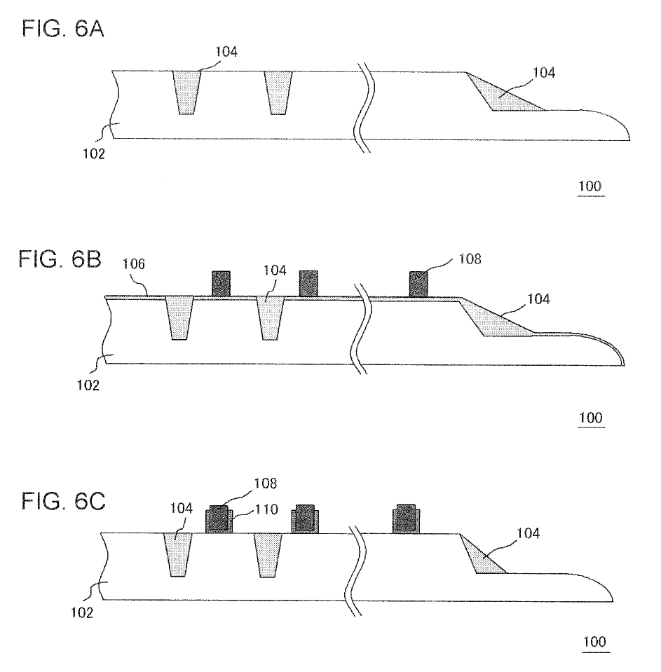

With reference to FIGS. 6A to 6C to FIGS. 12A to 12C, a procedure of manufacturing the semiconductor device 100 will be described concretely. In the following, the case where the first width L₁ and the second width L₂ described with reference to FIG. 5 are almost equal to each other will be described as an example.

FIG. 6A shows a state where a device isolation insulating film 104 is formed on the wafer 102. Only an upper part of the wafer 102 is shown in the diagram.

In such a state, a gate insulating film 106 is formed on the entire face of the wafer 102 and, further, a conductive material constructing a gate electrode is applied thereon. The gate insulating film 106 is, for example, a silicon oxide film, a high-dielectric-constant film, or the like. The conductive material may be composed of polysilicon or the like. By patterning the conductive material into the shape of the gate electrode, a gate electrode 108 is formed (FIG. 6B) After that, an offset spacer 110 is formed on the side walls of the gate electrode 108 (FIG. 6C). The offset spacer 110 can be constructed by, for example, a silicon oxide film or the like.

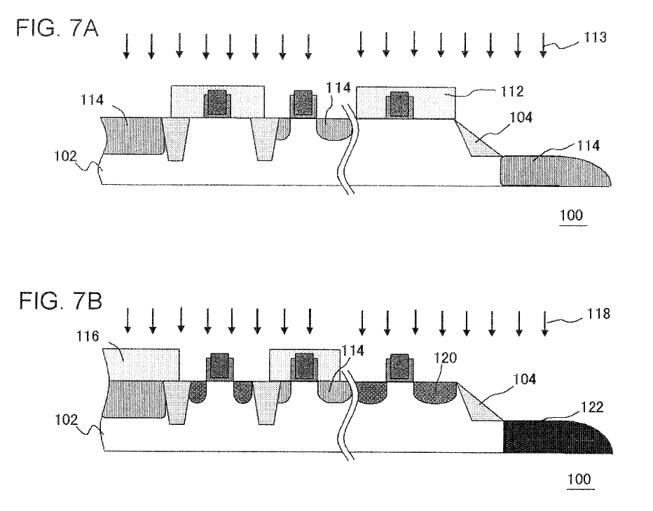

Subsequently, by implanting N-type impurity ions 113 into the wafer 102, an N-type impurity diffusion layer 114 is formed. The N-type impurity ions 113 are implanted into places to be a source-drain region of an N-type transistor and an extension region. In the implantation, a region in which a P-type transistor is to be formed is protected with a resist film 112 so that the N-type impurity ions 113 are not implanted (FIG. 7A). In the embodiment, each of the resist films may be subjected to back rinse and side rinse in a procedure which will be described later and may be formed in a state where an outer peripheral region is removed.

After that, P-type impurity ions 118 are implanted in the wafer 102 to form a P-type impurity diffusion layer 120. The P-type impurity ions 118 are implanted into places to be a source-drain region of a P-type transistor and an extension region. In the implantation, a region in which an N-type transistor is to be formed is protected with a resist film 116 so that the P-type impurity ions 118 are not implanted. However, the outer peripheral region of the wafer 102 is exposed in each of the process of implanting the N-type impurity ions 113 and the process of implanting the P-type impurity ions 118, so that the N-type impurity ions 113 and the P-type impurity ions 118 are implanted, and a high-concentration impurity diffusion layer 122 having high concentration of the impurity ions is formed (FIG. 7B)

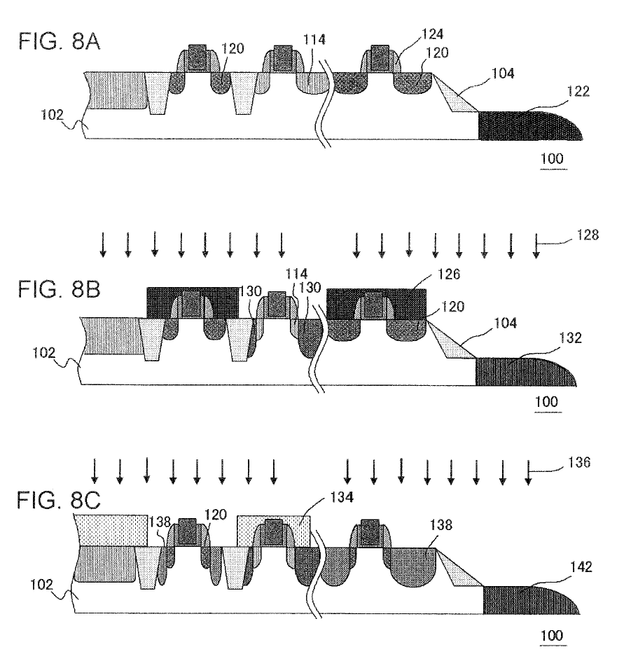

After that, side walls 124 are further formed on the side walls of the offset spacer 110 of the gate electrode 108 (FIG. 8A).

Subsequently, N-type impurity ions 128 are implanted in the wafer 102 to form an N-type impurity diffusion layer 130. The N-type impurity ions 128 are implanted in a place to be a source/drain region of an N-type transistor. In the implantation, a region in which a P-type transistor is to be formed is protected with a resist film 126 so that the N-type impurity ions 128 are not implanted. However, since the resist film 126 is not formed in the outer peripheral region of the wafer 102, the N-type impurity ions 128 are implanted, and a high-concentration impurity diffusion layer 132 having higher concentration than that of the high-concentration impurity diffusion layer 122 is formed (FIG. 8B).

Subsequently, P-type impurity ions 136 are implanted in the wafer 102 to form a P-type impurity diffusion layer 138 (FIG. 8C). The P-type impurity ions 136 are implanted in a place to be a source/drain region of a P-type transistor. In the implantation, a region in which an N-type transistor is to be formed is protected with a resist film 134 so that the P-type impurity ions 136 are not implanted. However, since the resist film 134 is not formed in the outer peripheral region of the wafer 102, the P-type impurity ions 136 are implanted, and a high-concentration impurity diffusion layer 142 having higher concentration than that of the high-concentration impurity diffusion layer 132 is formed.

The N-type impurity ions 128 and the P-type impurity ions 136 specify the impurity concentration of the source/drain region of a transistor. The impurity ions of considerably high concentration are implanted. For example, the concentration of each of the N-type impurity ions 128 and the P-type impurity ions 136 is 1E15 atons/cm² or higher. Consequently, two kinds of impurity ions of very high concentration are implanted in the high-concentration impurity diffusion layer 142. Due to the fact, when a silicide layer is formed on the region, a problem occurs such that the layer is peeled off.

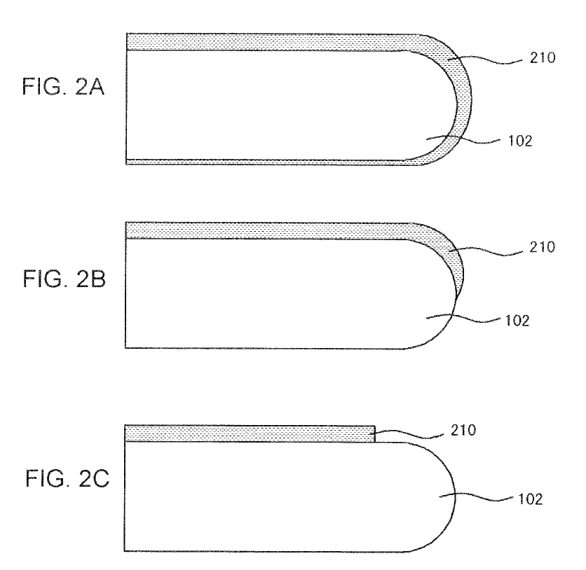

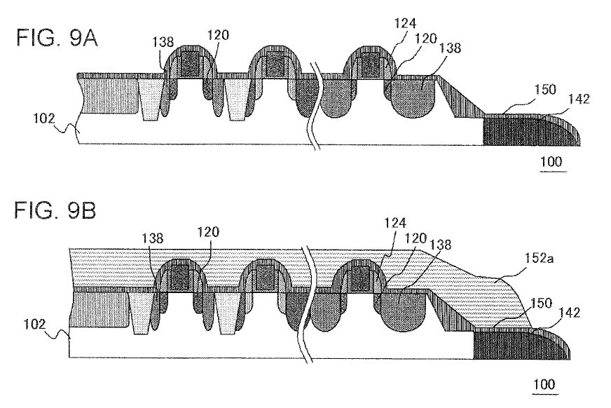

Subsequently, a silicide block insulating film 150 is formed on the entire surface of the wafer 102 (FIG. 9A). After that, a negative resist material 152a is applied on the entire surface of the wafer 102 (FIG. 9B). Then, as described with reference to FIGS. 2A to 2C, the back rinse and the side rinse are performed.

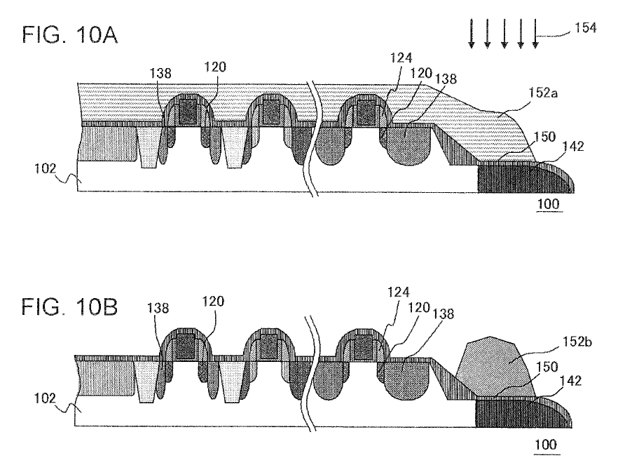

Peripheral exposure 154 for annularly exposing the peripheral part of the negative resist material 152a (FIG. 10A) is performed. As described with reference to FIGS. 5A to 5C, the peripheral exposure 154 is performed so that the inner edge of the annular pattern is positioned on the inner peripheral side of the inner edge of the region in which both of the N-type impurity ions 128 and the P-type impurity ions 136 are implanted. As described with reference to FIG. 16, the peripheral exposure 154 is performed so that the outer edge of the annular pattern is positioned on the outer peripheral side more than the inner edge of the region in which a metal layer 160 is not formed with a shadow ring used at the time of forming the metal layer 160 later. After that, development is performed. As a result, the negative resist material 152a other than the part exposed by the process of FIG. 10a is removed, and a negative resist film 152b having an annular shape is formed in the peripheral part of the wafer 102 (FIG. 10B).

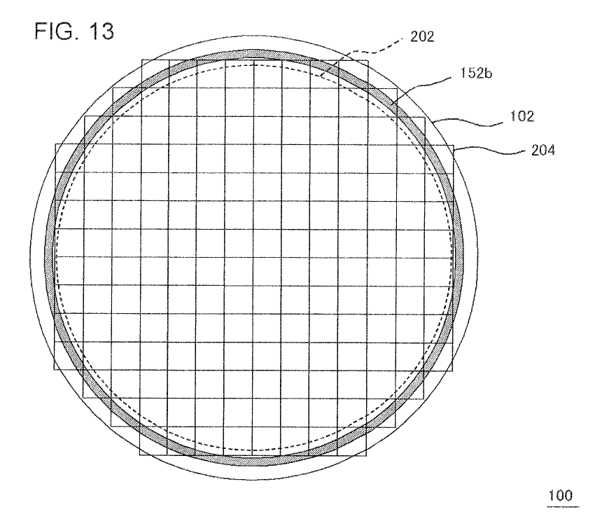

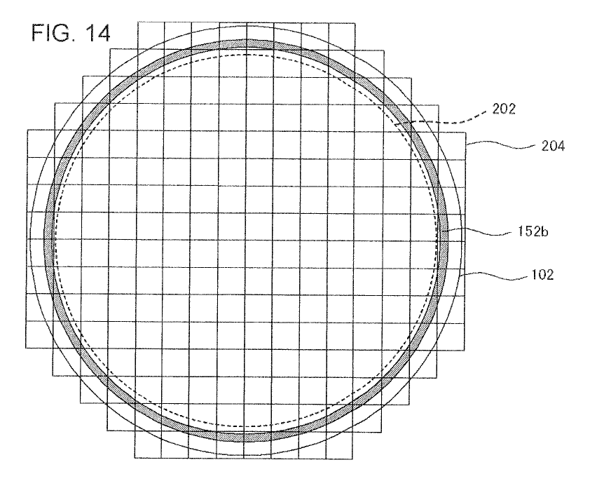

FIGS. 13 and 14 are plan views showing a state where the negative resist film 152b is formed on the wafer 102. FIG. 13 shows the case of the normal shot. FIG. 14 shows the case of the full-face shot. Although an example of providing the annular pattern of the negative resist film 152b around the valid region 202 of the wafer 102 is shown, the annular pattern of the negative resist film 152b may be provided on the inner periphery of the valid region 202.

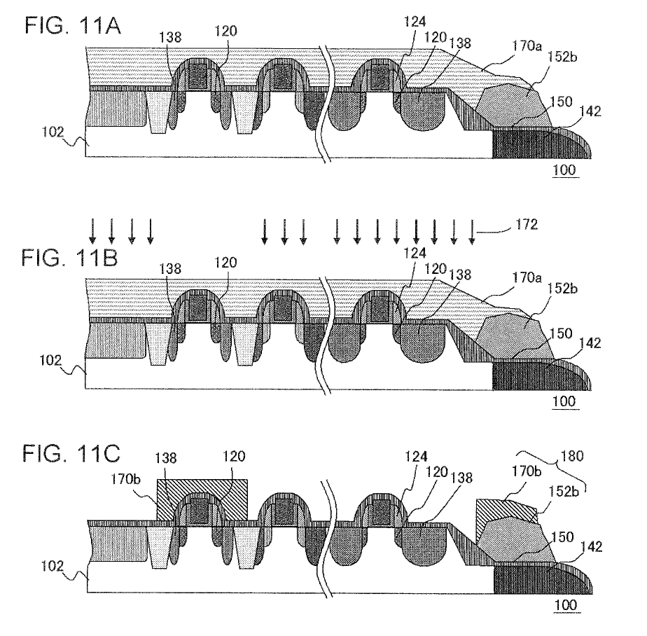

Referring again to FIGS. 11A to 11C a positive resist material 170a is applied to the entire surface of the wafer 102. Subsequently, as described with reference to FIGS. 2A to 2C, the back rinse and -the side rinse is performed (FIG. 11A).

After that, using a reticle having an opening in a place where a silicide layer is desired to be formed, step exposure 172 for patterning the silicide block Insulating film is performed on the positive resist material 170a (FIG. 11B) After that, development is performed. As a result, the positive resist material 170a in the place exposed by the process of FIG. 11B is removed, and a positive resist film 170b that selectively masks the place where a silicide layer is not formed is formed (FIG. 11C).

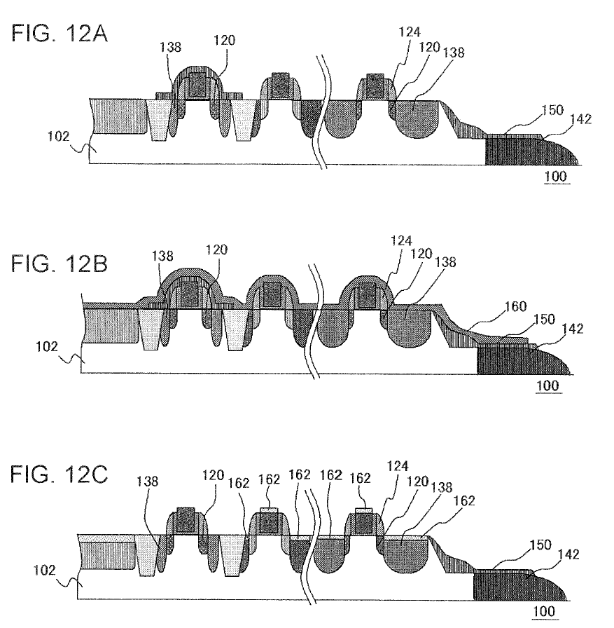

Subsequently, using a stacked resist film 180 constructed by the negative resist film 152b and the positive resist film 170b, the silicide block insulating film 150 is etched. After that, the stacked resist film 180 is removed. As a result, the wafer 102 in the place in which a silicide layer is to be formed later is selectively exposed (FIG. 12A).

A metal layer 160 is formed on the entire surface of the wafer 102 (FIG. 12B) The metal layer 160 can be formed by using, for example, cobalt, nickel, or the like by sputtering.

Reaction is caused between the metal layer 160 and silicon (the wafer 102) by lamp anneal or the like to form a silicide layer 162 at the place where the silicide block insulating film 150 is removed and the metal layer 160 and the silicon (the wafer 102 are in contact with each other (FIG. 12C). The silicide layer 162 may be, for example, a cobalt silicide layer, a nickel silicide layer, or the like.

Effects of the procedure of manufacturing the semiconductor device 100 in the embodiment will now be described.

In the semiconductor device 100 in the embodiment, while forming the annular pattern of the resist film in the outer peripheral part of the wafer 102 to protect the part, patterning of high resolution can be performed in the valid region in the wafer.

As described in JP-A No. 2006-294759, when a shadow ring is used at the time of forming a silicide layer, there is a case that the metal layer in the outer peripheral part becomes thin, and the silicide formation phase in the part changes. Consequently, at the time of performing residual etching on the metal layer, the surface of the silicide layer is oxidized, and a silicide layer having a film quality different from that of the effective region on the inside is formed. When such an oxide film is formed on the surface of the silicide layer, in the case of forming an insulating film such as an SiN film on the silicide layer, a problem of peeling-off of the insulating film occurs. On the other hand, by the process of manufacturing the semiconductor device 100 in the embodiment, it is unnecessary to use a shadow ring at the time of forming the silicide layer. Therefore, the silicide layer can be formed almost uniformly on the entire surface, and the silicide formation phase on the entire face can be made uniform.

By the procedure of manufacturing the semiconductor device 100 in the embodiment, the end part of the silicide layer 162 can be controlled so as not to be positioned on the high-concentration impurity diffusion layer 142 in which both of the P-type impurity ions and the N-type impurity ions are implanted, and peeling-off of the silicide layer 162 can be prevented.

### Second Embodiment

In the embodiment, a case of using a negative resist film at the time of patterning a silicide block insulating film formed so as riot to form a silicide layer at the time of forming a silicide layer on the surface of a wafer will be described as an example.

Also in the embodiment, by a procedure similar to that described with reference to FIG. 3 in the first embodiment, the semiconductor device 100 is formed The embodiment is different from the first embodiment with respect to only a resist film forming process in step S204 in FIG. 3.

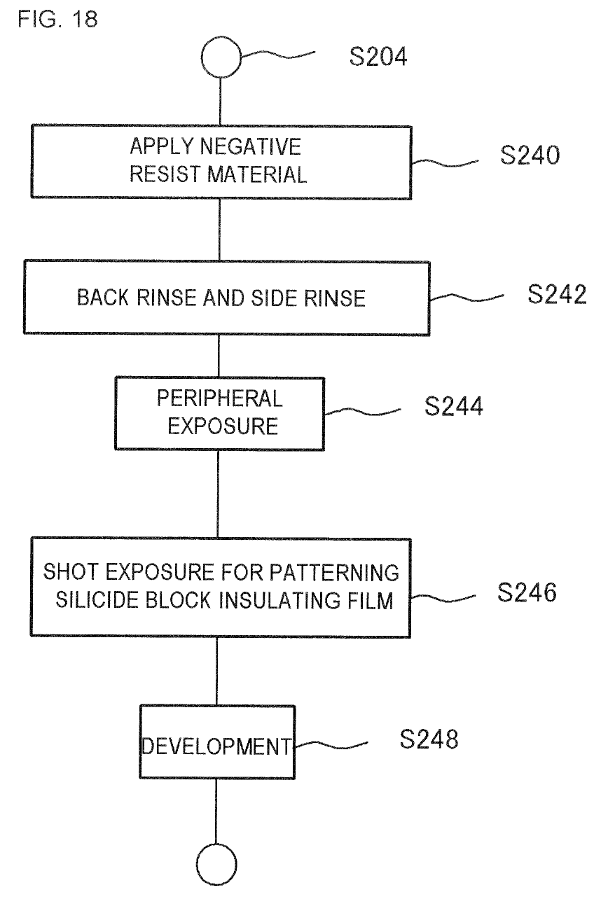

FIG. 18 is a flowchart showing a procedure of forming a resist film in the embodiment.

First, a negative resist material is applied to the entire surface of a wafer (S240). Subsequently, the back and sides are rinsed (S242). After that, peripheral exposure of annularly exposing a peripheral part of the wafer is performed (S244). While irradiating the negative resist material in an outer peripheral part of the wafer with light from an exposure source, the wafer is rotated relative to the exposure source. It is sufficient to rotate the wafer relative to the exposure source. By fixing either the wafer or the exposure source and rotating the other, the peripheral exposure may be performed. Subsequently, using a reticle that blocks a part in which a silicide layer is desired to be formed, shot exposure for patterning the silicide block insulating film is performed a plurality of times (S246) and development is performed (S248). As a result, a negative resist film remaining in an annular shape in the peripheral part of the wafer and having an open region in which a silicide layer is desired to be formed is formed in the valid region 202.

After that, by performing processes similar to those of the first embodiment, an end part of the silicide layer can be controlled so as not to be positioned on the region in which high-concentration impurity ions are implanted, in the outer peripheral part of the wafer.

Referring to FIGS. 6A to 6C to FIGS. 9A and 9B, FIGS. 19A to 19C, and FIGS. 12A to 12C, a procedure of manufacturing the semiconductor device 100 will be concretely described.

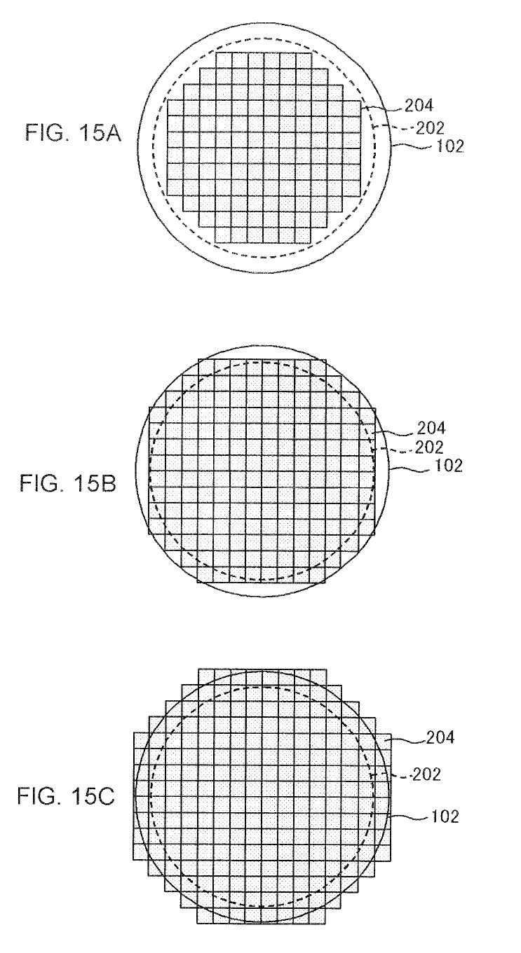

First, by a procedure similar to that described with reference to FIGS. 6A to 60 to FIGS. 9A and 9B in the first embodiment, the negative resist material 152a is formed on the wafer 102 as shown in FIG. 9B.

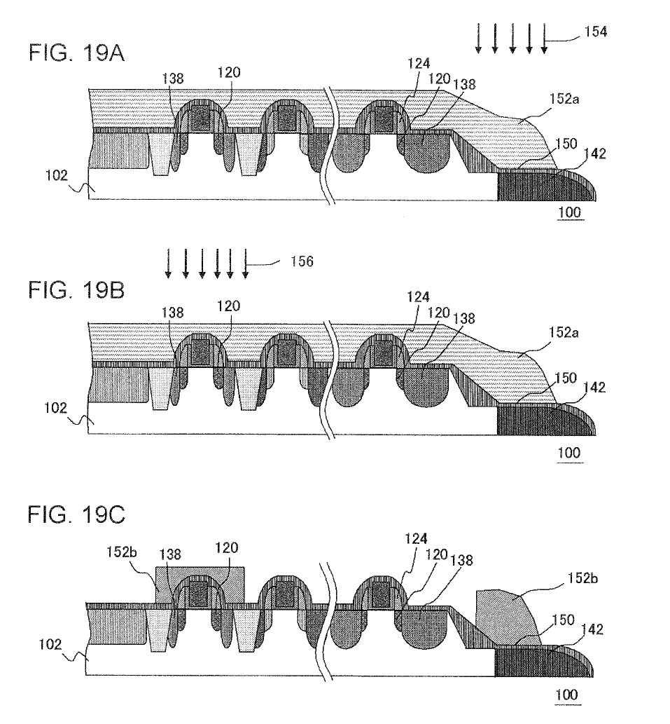

Subsequently, the peripheral exposure 154 of annularly exposing a peripheral part of the negative resist material 152a is performed (FIG. 19A). After that, using a reticle that blocks a part in which a silicide layer is desired to be formed, the shot exposure 156 for patterning the silicide block insulating film is performed on the negative resist material 152a (FIG. 19B), and development is performed. As a result, the negative resist film 152a existing on the outside of the part exposed by the process of FIG. 19A and the part exposed by the process of FIG. 19B is removed and remains in an annular shape in the peripheral part of the wafer 102 In the valid region 202, the negative resist film 152b having an open region in which a silicide layer is desired to be formed is formed (FIG. 19C).

Using the negative resist film 152b, the silicide block insulating film 150 is etched. After that, the negative resist film 152b is removed. By the process, the wafer 102 in a part in which a silicide layer is to be formed later is selectively exposed (refer to FIG. 12A). By a procedure similar to that described with reference to FIGS. 12A to 12C in the first embodiment, the silicide layer 162 is formed.

In the embodiment as well, effects similar to those of the first embodiment can be obtained. If patterning of necessary resolution can be performed also in the case of using the negative resist film, by using the negative resist film, the annular pattern that masks the peripheral part of the wafer and the patterning on the inside of the valid region 202 can be formed simultaneously by a single developing process, so that the process can be simplified.

Although the embodiments of the present invention have been described above with reference to the drawings, they are just examples of the present invention. Various configurations other than the above can be also employed.

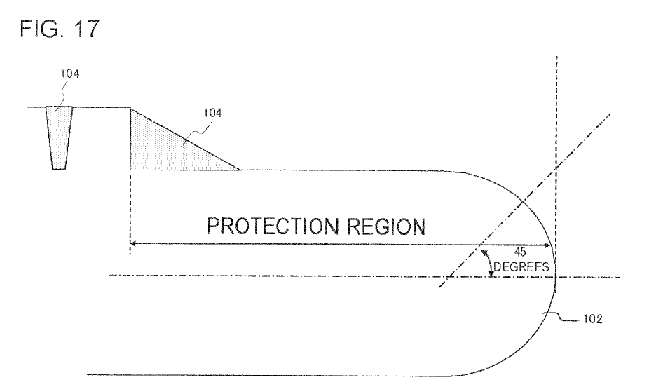

In the foregoing embodiments, the case of using the shadow ring at the time of forming the metal layer 160 has been described as an example. As another example, the present invention may be also applied to the case of using no shadow ring. FIG. 17 is a diagram showing an example of using no shadow ring at the time of forming the metal layer 160. In this case, the silicide block insulating film may be formed to the end face of the wafer 102 as much as possible. Specifically, only the back is rinsed in step S222 shown in FIG. 4, the negative resist material 152a is left near to the end face of the wafer 102, and the peripheral exposure can be performed by emitting light at an angle of about 45 degrees with respect to the center line in the plane direction of the wafer 102. In this case, the width of the annular pattern of the negative resist film 152b may be set to, for example, about 2.5 mm to 3 mm.

It is apparent that the present invention is not limited to the above embodiments, and may be modified and changed without departing from the scope and spirit of the invention.

What is claimed is:

1. A method of manufacturing a semiconductor device, comprising:
forming a negative resist film having an annular pattern that masks an outer peripheral part of a wafer, on a film to be processed which is formed on said wafer;
forming a positive resist film having a predetermined pattern on said negative resist film; and
etching said film to be processed using said negative resist film and said positive resist film as a mask.

2. The method according to claim 1, wherein in said forming the negative resist film, said annular pattern of said negative resist film is obtained by removing an outer peripheral region having a predetermined width from an outer edge of said wafer.

3. The method according to claim 1,
wherein said forming the negative resist film includes:
applying a negative resist material to an entire surface of said wafer; and
performing peripheral exposure on said negative resist material, of rotating said wafer relative to an exposure source while irradiating an outer peripheral part of said wafer with light from said exposure source.

4. The method according to claim 1,
wherein a valid region in which a valid chip is-to be formed is provided in an inner peripheral part apart from said outer edge of said wafer by a predetermined distance, on said wafer,
said forming the positive resist film Includes
applying a positive resist material to the entire surface of said wafer; and
performing shot exposure using a reticle having a predetermined pattern every predetermined range on said positive resist material, and
in said performing shot exposure, the shot exposure is also performed on the outside of said valid region.

5. A method of manufacturing a semiconductor device, comprising:
forming a first resist film on a wafer, said first resist film being obtained by removing a first outer peripheral region having a first width from an outer edge of said wafer and, using said first resist film as a mask, implanting impurity ions of a first conductive type into said wafer;
forming a second resist film on said wafer, said second resist film being obtained by removing a second outer peripheral region having a second width from said outer edge of said wafer arid, using said second resist film as a mask, implanting impurity ions of a second conductive type into said wafer;
forming a block insulating film on the entire surface of said wafer;
forming a third resist film having a first pattern on said block insulating film and patterning said block insulating film with said third resist film; and
forming a silicide layer on said wafer using said block insulating film as a mask,
wherein in said patterning the block insulating film, said first pattern of said third resist film includes an annular pattern that masks an outer peripheral part of said wafer, and an inner edge of said annular pattern is positioned on an inner peripheral side of at least an inner edge of a region where said first and second outer peripheral regions overlap.

6. The method according to claim 5,
wherein said first width and said second width are different from each other, and
the inner edge of the annular pattern that masks the outer peripheral part of said wafer is positioned on the inner peripheral side of the inner edge of said first or second outer peripheral region which is positioned on the inner peripheral side more than the other region.

7. The method according to claim 5,
wherein said first width of said first outer peripheral region and said second width of said second outer peripheral region are equal to each other.

8. The method according to claim 5,
wherein said implanting impurity ions of said first conductive type into said wafer and said implanting impurity ions of said second conductive type into said wafer are each performed to form a source/drain region of a transistor.

9. The method according to claim 5,
wherein said annular pattern that masks the outer peripheral part of said wafer is obtained by removing a third outer peripheral region having a third width from said outer edge of said wafer.

10. The method according to claim 5,
wherein said patterning the block insulating film includes:
forming a negative resist film having said annular pattern on said block insulating film,
forming a positive resist film having a second pattern on said negative resist film, and
forming said first pattern using said negative resist film and said positive resist film as masks, and etching said block insulating film.

11. The method according to claim 10,
wherein said forming the negative resist film includes:
applying a negative resist material to the entire surface of said wafer; and
performing peripheral exposure on said negative resist material, of rotating said wafer relative to an exposure source while irradiating an outer peripheral part of said wafer with light from said exposure source.

12. The method according to claim 10,
wherein a valid region in which a valid chip is to be formed is provided in an inner peripheral part apart from the outer edge of said wafer by a predetermined distance, on said wafer,
said forming the positive resist film includes:
applying a positive resist material to the entire surface of said wafer; and
performing shot exposure using a reticle having said second pattern every predetermined range on said positive resist material, and
in said performing shot exposure, the shot exposure is also performed on the outside of said valid region.

13. The method according to claim 5,
wherein said patterning the block insulating film includes:
applying a negative resist material to the entire surface of said wafer;
performing peripheral exposure on said negative resist material, of rotating said wafer relative to an exposure source while irradiating an outer peripheral part of said wafer with light from said exposure source; and
performing shot exposure using a reticle having a third pattern every predetermined range on said negative resist material.

14. The method according to claim 13,
wherein a valid region in which a valid chip is to be formed is provided in an inner peripheral part apart from the outer edge of said wafer by a predetermined distance, on said wafer, and
in said performing shot exposure, the shot exposure is also performed on the outside of said valid region.
